(19) United States
(12) Patent Application Publication
(10) Pub. No.: US 2002/0191660 A1
(43) Pub. Date: Dec. 19, 2002

(54) Anti-reflection coatings for semiconductor lasers

(76) Inventors: Andreas Wittman, Kilchberg (CH); Michael Solar, Zurich (CH); Ernst-Eberhard Latta, Adliswill (CH); Martin Krejci, Zurich (CH); Tim Kellner, Zurich (CH)

Correspondence Address: Lee, Mann, Smith,, McWilliams, Sweeney & Ohlson, P.O. Box 2786, Chicago, IL, 60690-2786, US

(21) Appl. No.: 09/993,824

(22) Filed: Nov. 6, 2001

Related U.S. Application Data
(60) Provisional application No. 60/293,738, filed on May 25, 2001.

(51) Int. Cl. H01S 5/00

(52) U.S. Cl. 372/49

(57) ABSTRACT

A semiconductor laser arranged to emit at a given wavelength has a light emitting facet carrying a phase-shifting anti-reflection coating, whose thickness is one quarter that of the given wavelength. Coupling at the light emitting facet is arranged to take place at the minimum of the standing wave.

### FIELD OF THE INVENTION

The present invention relates to semi-conductor lasers in general, and in particular to anti-reflection coatings therefor.

### BACKGROUND TO THE INVENTION

In semiconductor lasers, high power densities at the interface wave-guide to mirror, are responsible for gradual degradation close to the facet. In addition, the maximum extractable intensity at the physical interface semiconductor/coating is limited because of the catastrophic optical damage (COD). In the past, there have been efforts to increase the maximal output power by applying multiple layers of dielectrics, which reduces the power density at the interface as, for example, in the disclosures of G. Tompson “Antireflection coatings for injection lasers” (U.S. Pat. No. 3,943,462) and M. Gasser, E. -E. Latta, A. Jakubowicz, H. -P. Dietrich, P. Roentgen: “Semiconductor laser and method for making the same” (U.S. Pat. No. 5,940,424).

In addition, multiple Quarter-Wave layers have been used in stacks of alternating high and low indices to generate high reflection coatings. Generally, quarter-wave coatings are very non-sensitive against thickness and wavelength deviations.

Applying multiple layers of coatings adds to the complexity of the production process.

In previously known technologies, the desired reflectivity target is obtained by varying the thickness at constant optical index.

### OBJECT OF THE INVENTION

The invention seeks to provide an improved semiconductor laser which mitigates one or more of the problems associated with the prior art.

### SUMMARY OF THE INVENTION

According to a first aspect of the present invention there is provided a semiconductor laser arranged to emit at a given wavelength and having a light emitting facet carrying a phase-shifting anti-reflection coating, whose thickness is one quarter that of the given wavelength.

In a preferred embodiment, the coating is of SixOyNy:H.

Preferably, the coating is grown by Plasma-Enhanced Chemical Vapour Deposition (PECVD).

In a preferred embodiment, the laser is a GaAs laser.

Preferably, the coating has an optical index of at least 1.83.

Preferably, coupling is arranged to take place at the minimum of the standing wave.

The invention also provides for a system for the purposes of communications which comprises one or more instances of apparatus embodying the present invention, together with other additional apparatus.

The invention also provides for a method of manufacturing a semiconductor laser.

In particular, according to a further aspect of the present invention there is provided a method of manufacturing a semiconductor laser arranged to emit at a given wavelength and having a light emitting facet, the method comprising the steps of: forming an anti-reflection coating layer on the emission face, such that the layer thickness is one quarter of the given wavelength.

In a preferred embodiment, the coating is of SixOyNy:H.

Preferably, the coating is grown by PECVD.

In a preferred embodiment, the laser is a GaAs laser.

Preferably, the coating has an optical index of at least 1.83.

Preferably, coupling is arranged to take place at the minimum of the standing wave.

The laser may be employed in an optical transmitter or amplifier.

The preferred features may be combined as appropriate, as would be apparent to a skilled person, and may be combined with any of the aspects of the invention.

### BRIEF DESCRIPTION OF THE DRAWINGS

In order to show how the invention may be carried into effect, embodiments of the invention are now described below by way of example only and with reference to the accompanying figures in which:

FIG. 1 shows a schematic diagram of a semiconductor laser in accordance with the present invention;

FIG. 2 shows a graph of percentage reflectors against index of coating material in accordance with the present invention;

FIG. 3 illustrates the relationship between the light intensity and surface interfaces in a laser according to the present invention;

FIGS. 4(a) and 4(b) show graphically the target reflectance of a conventional coating and a coating according to the present invention respectively;

FIGS. 5 and 6 illustrate example intensity distributions for coatings in accordance with the present invention;

FIG. 7 shows graphically experimental data relating to time to Catastrophic Optical Damage (COD) of a laser device in accordance with the present invention;

FIG. 8 shows graphically a comparison of the dependence of reflectance on thickness variation for known coatings and a coating in accordance with the present invention;

FIG. 9 shows graphically a comparison of the dependence of reflectance on index variation for known coatings and a coating in accordance with the present invention;

FIG. 10 shows graphically a comparison of the dependence of reflectance on wavelength variation for known coatings and a coating in accordance with the present invention.

### DETAILED DESCRIPTION OF INVENTION

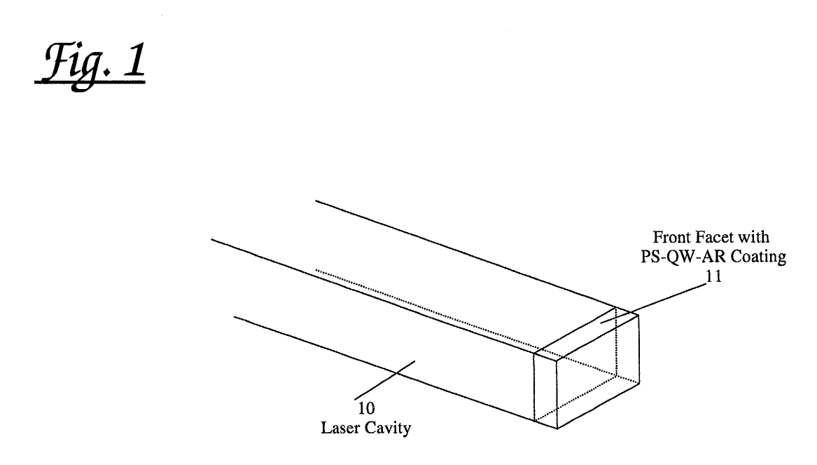

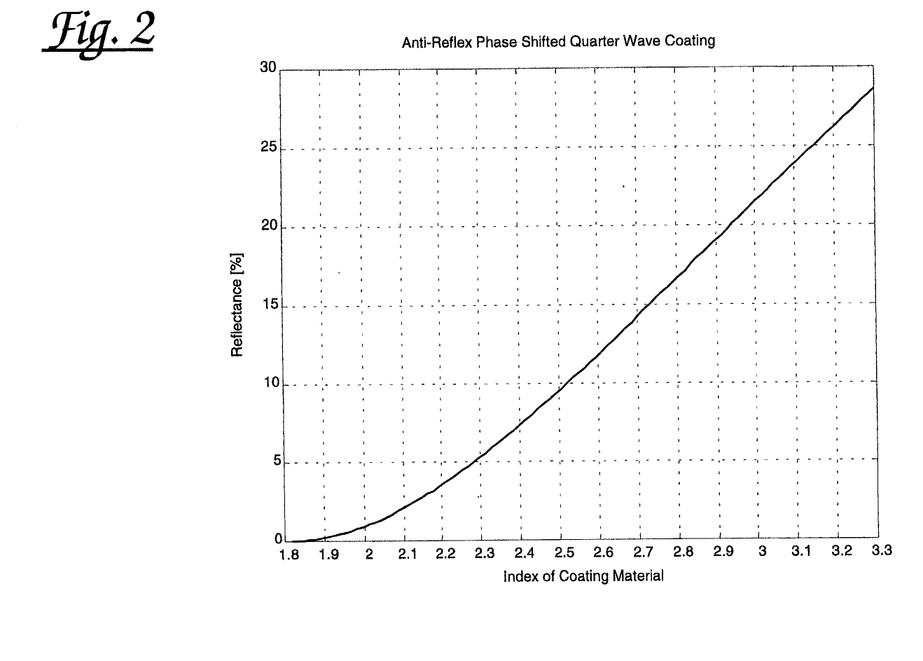

Referring to FIG. 1, there is shown a schematic diagram of a semiconductor laser comprising a laser cavity 10 and a front facet coating 11. The thickness of the front facet coating is chosen to be a quarter-wave of lasing wavelength and the optical index is varied to adjust the reflectivity. To obtain the phase-shifting properties the optical index has to be chosen higher than \sqrt{n_{sub}·n_{Amb}}. In the case of GaAs lasers operating in air, this requires an optical index larger than 1.83. FIG. 2 shows graphically the needed index for a target reflectivity.

Advantageously, coupling ideally takes place at the minimum of the standing wave and therefore stress at the interface semiconductor/coating minimized.

Furthermore, target reflectivity is non-sensitive against thickness variations and fluctuations of the lasing wavelength.

The method can also be applied in a high-throughput large-scale production due to the very simplicity and stability of the design using a single coating layer.

The invention was demonstrated by comparing a conventional front facet coating of 1490A thick and with an optical index of 1.815 with a phase-shifting quarter-wave front facet coating 1228A thick and with an optical index of 1.995.

The coating was of SixOyNy:H layers grown by PECVD. Generally any coating can be used for which the refractive index is adjustable. In the case of using a technology where there are discrete refractive indices, it is possible to use the invention for discrete reflectivities.

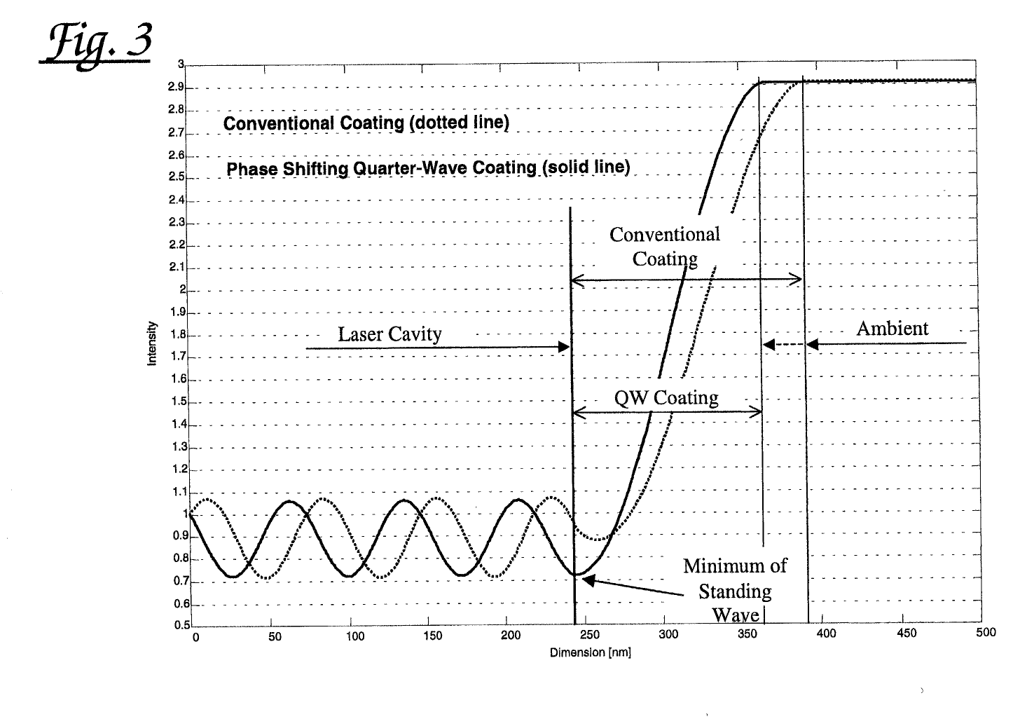

FIG. 3 illustrates how the phase-shifting quarter-wave coating couples exactly in the minimum of the standing wave. Laser tests were performed at the above coatings and compared with conventional coatings coupling near the maximum of the standing wave.

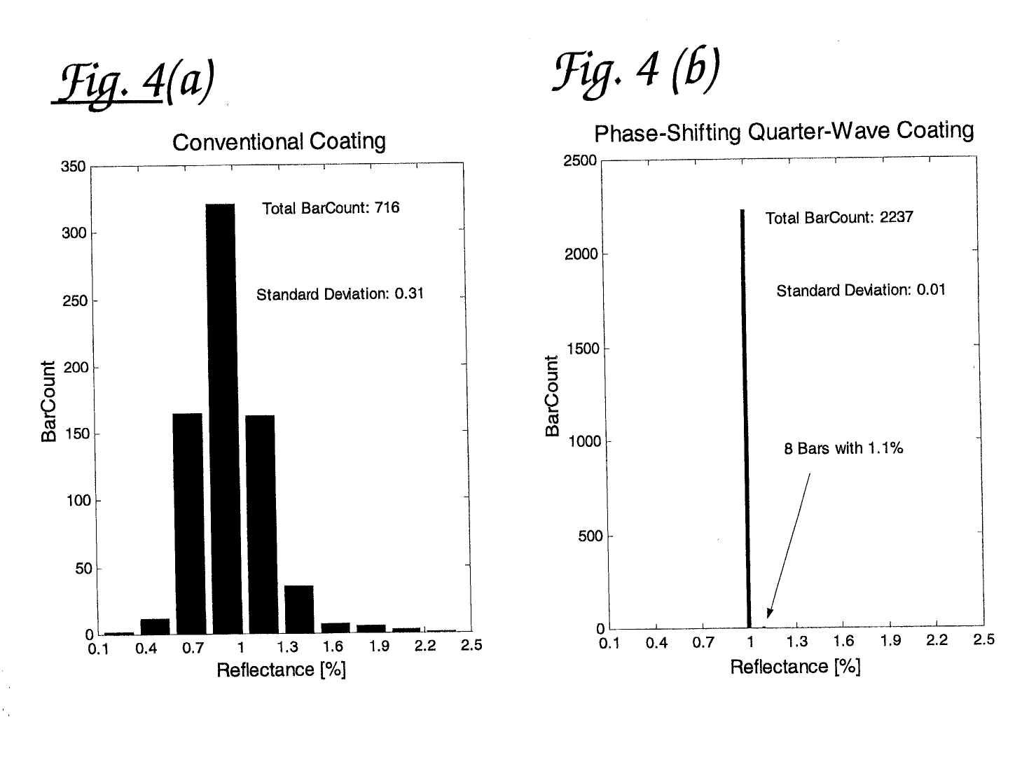

Referring now to FIGS. 4(c) and 4(b) it is seen that the target reflection of the new coating is an improvement over that of the conventional coating design.

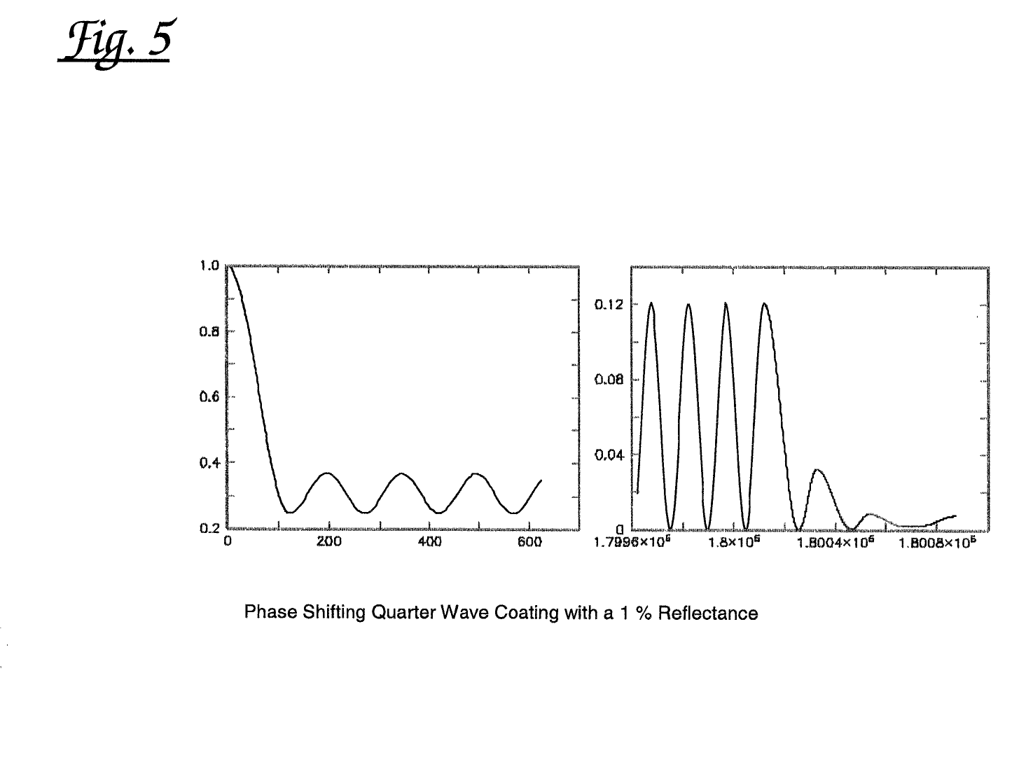

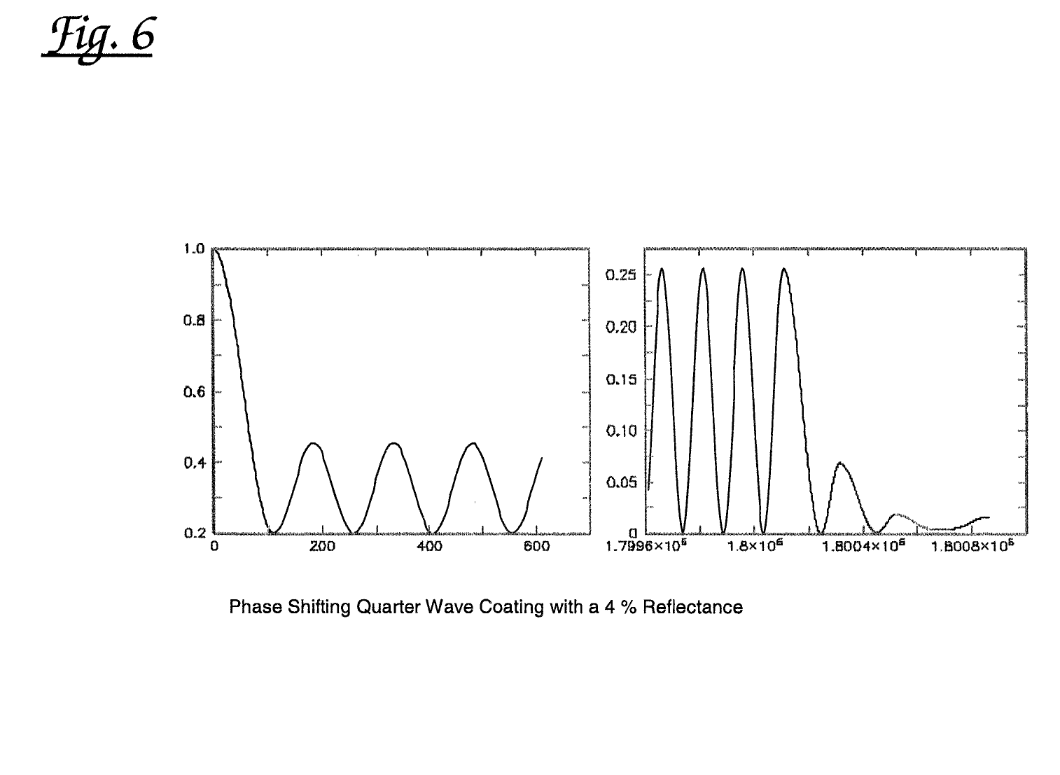

Referring now to FIGS. 5 and 6, the standing wave within the cavity and mirror coating is governed by the design of mirror. The phase-shifting design forces the standing wave at the interface laser-mirror to couple at the minimum of the standing wave.

The relative reduction intensity at the facet in respect to the maximal intensity was calculated for a 1% coating and a 4% coating.

Referring to FIG. 5, the two plots represents the intensity normalized for the front intensity (front facet is displayed on the left side). As can be seen, the application of the phase-shifting QW coating leads to a reduction of the intensity by 30%.

Referring to FIG. 6, the two plots represents the intensity normalized for the front intensity (front facet is displayed on the left side). The application of the phase-shifting QW coating leads to a reduction of the intensity by 55%.

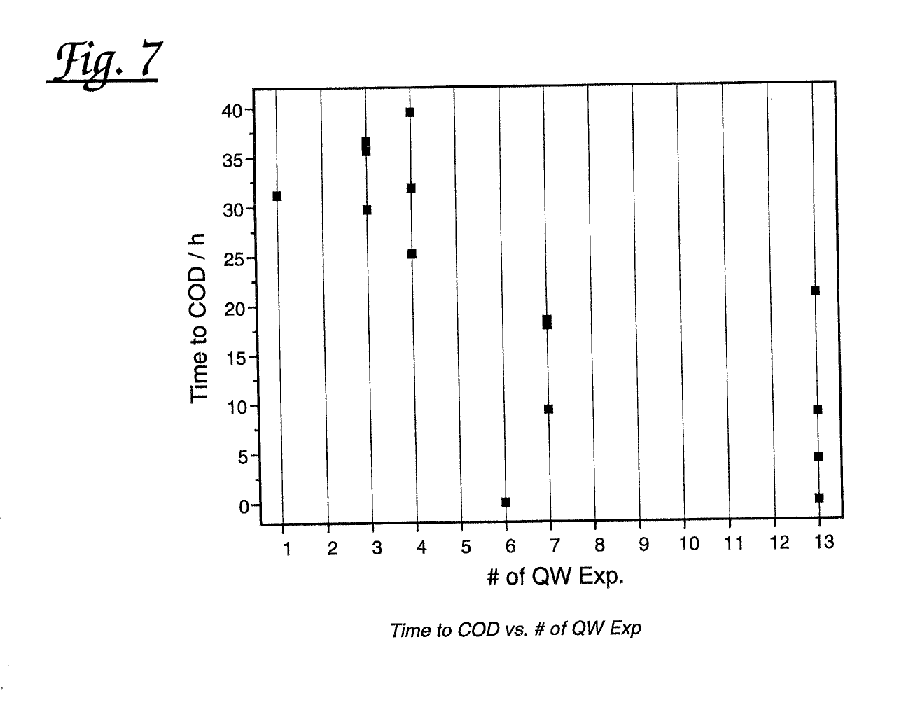

Referring now to FIG. 7, experimental results show clearly, that the COD level is much higher for the Phase Shifting Quarter-Wave Coating.

The new front mirror coating, was developed with the intention to minimize the influence of coating thickness and the wavelength on the reflectivity. As a result the reflectance distribution compared with today's standard coating is reduced from +/−0.8 down to +0.2/-0.01% of target reflectance. In addition, the dependence on wavelength—which cannot be taken into account in a high throughput production line—is negligible. Front-to-back distributions over one cell evidence this behavior. Furthermore, the design was performed with a high reflectance index to take advantage of reducing the laser intensity at the facet to zero. QW coatings having a high index show a significant higher COD level, which is believed to be due to this advanced design. Reliability data shows an equal or even better reliability for lasers with a QW coating by comparison to today's standard coating.

Due to the development of new product generations, which require a lower front mirror reflectance, a reduction of reflectance distribution is needed to satisfy customer specifications. The reflectance deviation is mainly governed by the strong dependence of the reflectance on a thickness deviation.

Furthermore, the reflectance is not only a function of coating thickness and refractive index, but on the wavelength of the emitted light. A deviation from the target wavelength affects the reflectance. This effect is unsuited for high throughput production, where multiple cells, differing in wavelength, are coated in the same coating run. Therefore, for a high throughput, a negligible wavelength dependence is required for the reflectivity of the coating.

In order to reduce the dependence of the reflectivity on wavelength and layer thickness, a quarter-wave (QW) coating design is chosen. In contrast to previous mirror design, the QW coating is designed to adapt the reflectance by refractive index instead of coating thickness.

A change in the refractive index results from a material change, therefore a big effort was invested in the development of PECVD processes for stable amorphous SiN:H materials with different refractive indices.

Materials with refractive indices lower than 1.83 (today's standard material index) and deposited by RF PECVD are not stable during long time annealing processes at 300° C. Fortunately, it was found that there are two indices where the same reflectance is obtained. Consequently, instead of the low index the high index was chosen.

The complementary refractive indices (high indices) show the positive effect of reducing the intensity at the interface between the laser material and the mirror to zero because the reflected wave is phase shifted by 180 degree to the incident wave. The same approach may be used to reduce the COD of coatings. Test results verify this theory.

For the G06d generation we suggest a QW mirror with a refractive index of 2.02 (measured by ellipsometry at 630 nm).

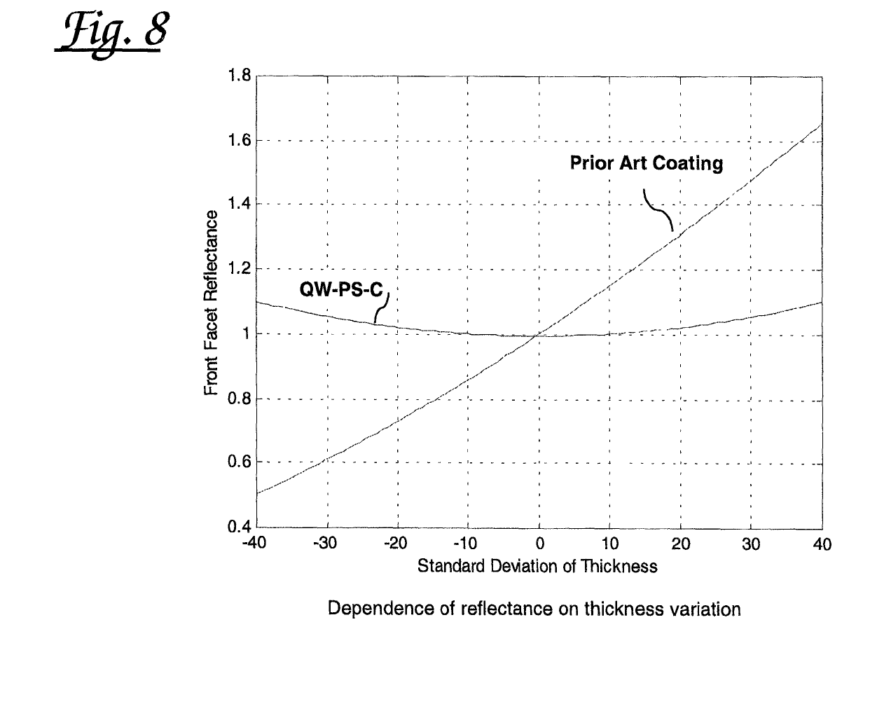

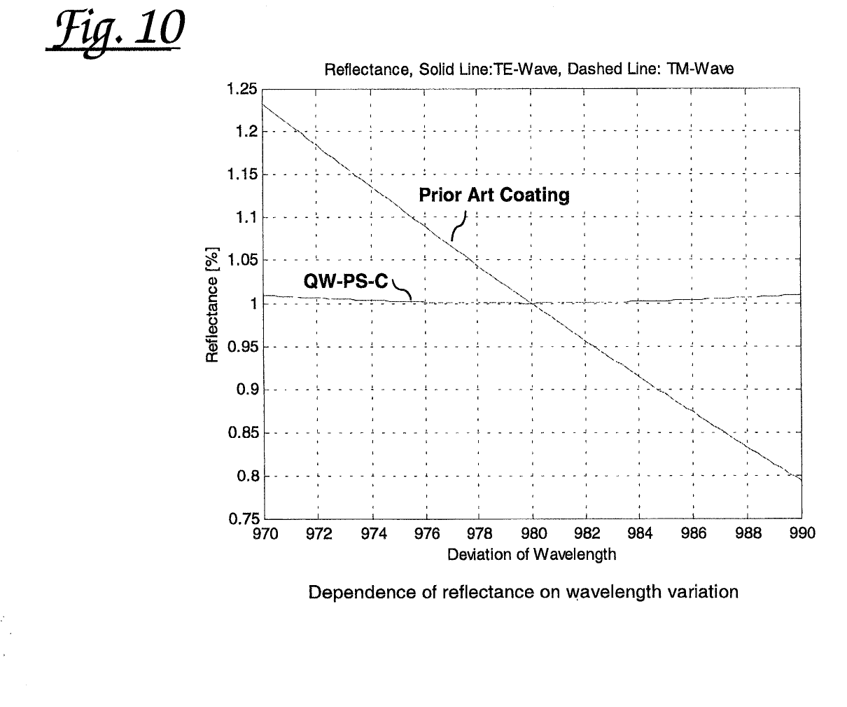

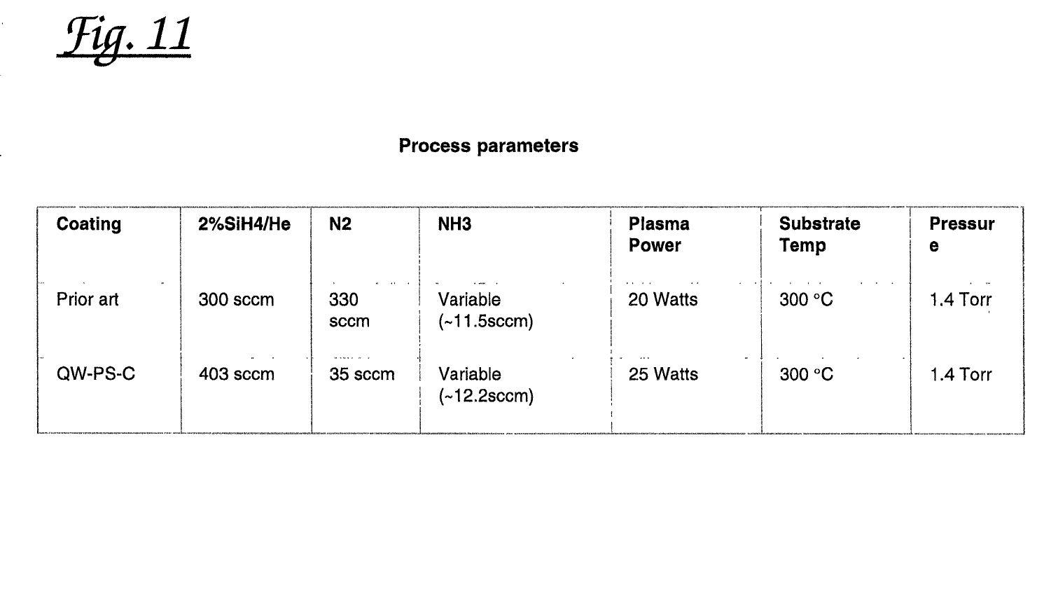

FIGS. 8-10 show the influence of thickness, refractive index and wavelength on the target reflectivity.

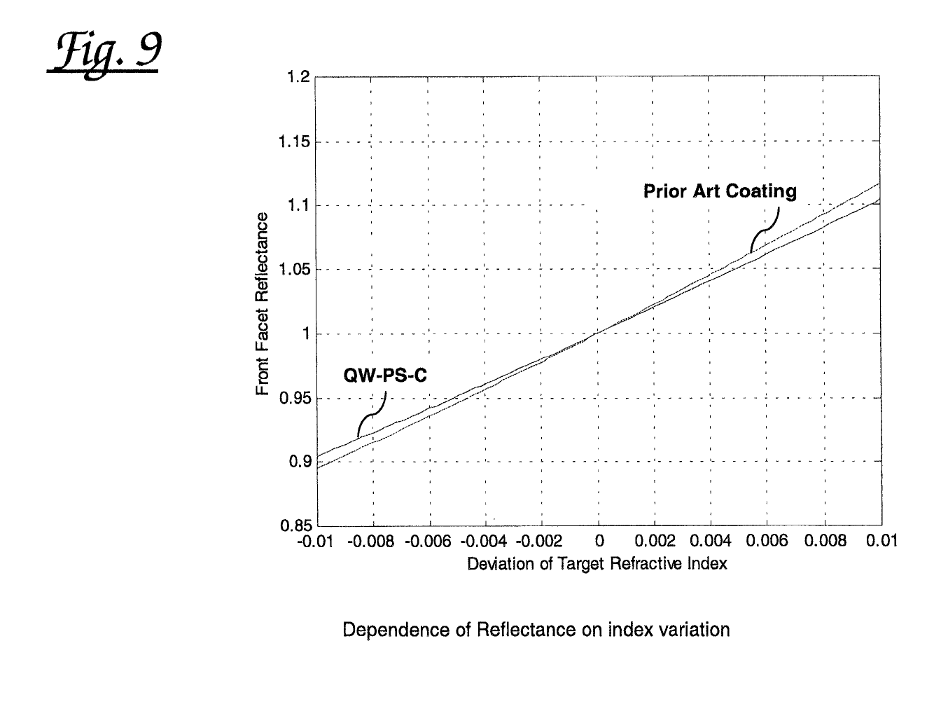

The greatest influence has a thickness deviation from the target thickness on the reflectance. In the plotted range, which represents today's standard deviation over one cell, the influence of a thickness variation is acceptable (FIG. 8). As it is seen in FIG. 9, the influence of the refractive index is comparable and contributes less to a deviation in reflectance than a thickness variation does.

As may be seen, prior art standard coating reflectance is strongly dependent on wavelength variation, whereas the present coating is absolute stable due to wavelength variations in the plotted range.

For the standard 1% coatings the reflectance variation is about +/−0.8 abs %. For the new coating the requirement for the maximal reflectance variation is as follows:

Reflectance Variation
+0.2/−0.01 abs %

This leads to the following requirements for thickness, index and wavelength:

| Thickness | | Wavelength |
|---|---|---|
| variation | Index variation | variation |
| +/−50 A | +0.005/−0.005 | +/−10nm |

These requirements concern the homogeneity and the run-to-run reproducibility of the coating process (see below).

An important criterion for front mirror coatings is the material degradation during laser operation. First experiments showed that the coating degradation is mainly related

the absorption of the emitting light (i.e. absorption at 980 nm) and

the thermal stability

of the coating material. For PECVD SiN:H layers these material properties are mainly governed by the amorphous crystal structure. The structure is characterized by the configurations and density of various bonds (Silicon-Nitrogen, Silicon-Silicon, Silicon-Hydrogen, Nitrogen-Nitrogen and Nitrogen-Hydrogen bonds) which were formed during the deposition process as a result of chemical reactions of the precursor gases Silane (SiH₄), Ammonia (NH₃) and Nitrogen (N₂). This chemical reaction and the resulting material properties of the SiN:H layers are mainly governed by the following process parameters:

1. [SiH₄]:[NH₃]:[N₂] ratios in the plasma

2. Total flux of the precursor gases

3. Plasma power

4. Pressure within the chamber

5. Substrate temperature

6. Addition of other precursor gases, e.g. Hydrogen

A change in refractive index is connected with a change in the amorphous crystal structure. Compared to the standard coating process (refractive index 1.83) the QW layer must contain more silicon and/or have a higher density. The change in the amorphous structure potentially leads to a change in absorption as well as in thermal stability. Especially the increase in Si—Si bonds might reduce the thermal stability of the layers, and it might lead to the formation of nitrogen free amorphous Si clusters which absorb light at 980 nm. The requirements for the new λ/4 process concerning absorption and thermal stability at 980 nm were set as follows:

The change in thickness and refractive index introduced by annealing (410° C., 45 min) in the QW-PSC SiN:H layers must be smaller than in annealed (410° C., 45 min) “standard” SiN:H layers.

The absorption of both λ/4 and standard coating is too small to be determined. However, AFM studies of earlier QW coatings on lasers revealed dimples in the coating which are related to the densification of the coating material during laser operation. This densification is a result of (a) the absorption of emitting light and (b) the thermal instability of the coating. This observation lead to the following third material stability criterion:

AFM investigations of QW-PS coated lasers of type G06a operated at 700 mA and 85° C. during 3000 h should show no dimples in the front coating.

Since a high ratio means a high probability of Silicon-Silicon bonds, the [Si]/[N] ratio should be close to 0.75. Based on material tests the Upper limit for the ratio was set to [Si]/[N]=1.5.

Elastic recoil detection analysis and Infrared spectroscopy measurements showed that there is no correlation between the total amount of hydrogen in the PECVD SiN:H layers and the thermal stability of the layers. The stability of the material depends on type of silicon-hydrogen and nitrogen-hydrogen bonds. Therefore no requirement was set for the total hydrogen concentration.

For all performed device tests (ESD, Pulsed time to COD measurements, Bar test results, degradation behaviour) the QW-PS coated lasers behave equally or better than same chip material with standard coating.

For the PECVD Process the same requirements as for the standard coating are valid. In first place these requirements concern:

The standard deviation for one batch of lasers should be in the same order of magnitude as for the standard coating:

+/−30 A from the target thickness,

and +/−0.001 for the refractive index within on holder.

The requirements for the run-to-run reproducibility, carried out on plain GaAs wafers, are the same as for the standard coating. The deviation from the target values should be

less than 20A for the layer thickness, and

less than 0.004 for the refractive index

The throughput should be the same as for the standard coating. Since there are multiple coating tools, there are no shortage due to different processes expected.

The QW-PS coating process for n=2.02 is a modification of the standard process, the parameters for which are shown in FIG. 11.

The change in plasma power from 20 to 25 Watts leads to a higher density and therefore to a better material stability. Reliability data of QW-PS coated laser chips (see below) indicates that the increase of the plasma power from 20 to 25 W results in no significant damage of the facet.

For a higher refractive index the [SiH4]/([NH3]+[N2]) flux ratio has to be increased.

Material tests have shown that an increase of the [NH₃]/[N₂] flux ratio improves the material stability of the SiN:H layers. However, some N₂ is needed in the plasma for homogeneity reasons. Therefore, the N₂ flux was reduced to 35 sccm.

For the investigation of the material properties and stability SiN:H layers (standard process, “old” λ/4 process, current “new” process as described above) deposited on GaAs and Si substrates were annealed at 410° C. during 1, 15 and 45 min. The following parameters and features of annealed and not annealed samples were compared.

Thickness and refractive index: The change of thickness and refractive index induced by the annealing steps is smaller for the QW-PS coating than for the standard coating.

Stoichiometry and density: Compared to “old” less stable versions of QW coatings (e.g. coating type “C”, plasma power 20 W), the QW-PSC process contains less Si (=>less Si—Si bonds) and has a higher density.

Hydrogen content: The hydrogen loss in the QW-PS coating induced by the annealing step is comparable to the standard coating and smaller than in previous QW processes

Etch rate in 1:49 buffered HF solution: The etch rates of standard and λ/4 coatings cannot be compared since the etch rates depends on the stoichiometry. However the etch rates are smaller for the new λ/4 process than for the old processes.

Si—H and N—H peaks of infrared spectra: The Si—H peaks in the spectra belonging to QW-PS layers are centered about 2180 cm⁻¹ which shows that the majority of the silicon-hydrogen bonds are stable S₁—H₂ bonds and which indicates the absence of nitrogen free Silicon-Hydrogen clusters. These clusters are thermally less stable, and they are and possibly responsible for absorption at 980 nm in “old” QW layers.

Stress: In contrary to the tensile stressed standard coating the stress in the QW-PS SiN:H layers is compressive. Test data indicates that this difference in stress behavior has not a negative impact on the reliability of the lasers. The change in stress due to annealing is about the same for the QW-PS and the standard coating.

Furthermore, several stress tests exhibit an about 20-30% lower fit rate for the Phase Shifting Quarter Wave Coating.

The material tests show clearly the improved material stability of the QW-PS coating process.

Device Tests

Bar Test

No coating related effects within all experiments concerning threshold current and front efficiency (besides the fact that a higher front facet reflectivity results in a lower threshold current and a lower front efficiency)

Front-to-back (FB) ratio is more stable (lower standard deviation) in comparison to standard SiN:H coating with the exception of a few QW coated bars which show a strong scattering of the FB ratio (no explanation yet).

Electrostatic Discharge (ESD) test (+9 kV to −9 kV) shows no significant difference between the standard SiN:H and the QW SiNH coated laser chips.

On the pulsed time to COD laser test (−40C, 2.5A, 5·s, 4% DC), all observed fails were CODs, i.e. the pulsed laser test stresses specifically the front facet of the laser diode. The average fail time proved to be lower for standard coated laser chips in comparison to QW coated laser chips

Degradation with respect to threshold current and efficiency during LT (700 mA, 85C)on LT for QW coated chips was observed to be lower than or in the order of standard coated chips.

Apart from the process control used for the standard coating, extra control steps will be introduced:

1. Control of stoichiometry: the composition of “pre-run” SiN:H layers will be measured by EDX (3 kV, 100 s). The Si/N ratio should not exceed the value 1.4 (Spec: 1.2-1.4).

2. Determination of etch rates: The etch rates of “pre-run” SiN:H layers in 1:49 buffered HF solution should not be higher than 50 nm/min.

1. A semiconductor laser arranged to emit at a given wavelength and having a light emitting facet carrying a phase-shifting anti-reflection coating, whose thickness is one quarter that of the given wavelength.

2. A semiconductor laser according to claim 1 in which the coating is of SixOyNy:H.

3. A semiconductor laser according to claim 2 in which the coating is growing by PE-CVD.

4. A semiconductor laser according to claim 1, being a GaAs laser.

5. A semiconductor laser according to claim 1 in which the coating has an optical index of at least 1.83.

6. A semiconductor laser according to claim 1 in which coupling is arranged to take place at the minimum of the standing wave.

7. A method of manufacturing a semiconductor laser arranged to emit at a given wavelength and having an emission face, the method comprising the steps of:
forming an anti-reflection coating layer on the emission face, such that the layer thickness is one quarter of the given wavelength.

8. A method according to claim 5 in which the coating is of SixOyNy:H.

9. A method according to claim 5 in which a coating is grown by PE_CVD

10. A method according to claim 5 in which the semiconductor laser is a GaAs laser.

11. A method according to claim 7 in which the coating has an optical index of at least 1.83.

12. A method according to claim 7 in which coupling is arranged to take place at the minimum of the standing wave.

13. An optical transmitter incorporating a laser as claimed in claim 1.

14. An optical amplifier incorporating a laser as claimed in claim 1.
